(19) United States
(12) Patent Application Publication
(10) Pub. No.: US 2010/0012165 A1
(43) Pub. Date: Jan. 21, 2010

(54) Self-Powered Electrical System

(76) Inventor: Mark Bedard, St. Lambert (CA)

Correspondence Address: MERCHANT & GOULD PC, P.O. BOX 2903, MINNEAPOLIS, MN, 55402-0903, US

(21) Appl. No.: 12/502,579

(22) Filed: Jul. 14, 2009

Related U.S. Application Data
(60) Provisional application No. 61/080,824, filed on Jul. 15, 2008.

(51) Int. Cl. H01L 35/30; F21L 4/00; F21L 4/02

(52) U.S. Cl. 136/205; 362/190; 362/184

(57) ABSTRACT

A portable self-powered electrical system for converting heat energy into electrical energy to power one or more electric devices, the portable self-powered electrical system comprises a housing, a thermoelectric device positioned in the housing, and a power transfer medium, wherein the thermoelectric device converts heat energy from a heat source into electrical energy for providing power to at least one electronic device via a power transfer medium.

### RELATED APPLICATION

This application claims the benefit of U.S. Patent Application Ser. No. 61,080,824 filed on Jul. 15, 2008, the entirety of which is hereby incorporated by reference.

### TECHNICAL FIELD

The present disclosure relates generally to self-powered electrical systems. More specifically, the present disclosure relates to portable self-powered electrical systems utilizing a thermoelectric effect to power one or more electrical accessories.

### BACKGROUND

Portable power sources are commonly used in situations where a mains power source is not readily available to power an electrical system or device. For example, it has been found advantageous to have a portable power source when participating in activities such as camping, traveling, or tailgating events.

One concern with current portable power sources relates to systems that are bulky and awkward to transport, such as electrical generators. Another concern relates to the use of disposable portable power sources such as disposable batteries that, for example, necessarily incur a reoccurring cost of having to repeatedly purchase the batteries.

For these and other reasons improvements are desirable.

### SUMMARY

The present invention addresses the need to make available a self-powered electrical system to provide a self-contained, portable and relatively maintenance free method to provide electrical power to an electrical device or accessory. In general, a self-powered electrical system is positioned near a heating source such that a thermoelectric device, integrally formed with the self-powered electrical system, can convert thermal energy into electric energy to power one or more electronic devices. It will be evident to those skilled in the art that, according to principles of the present disclosure, the self-powered electrical system can be realized in many different embodiments and may be employed in various other situations to provide electrical energy when a heat source is readily available.

### DESCRIPTION OF THE DRAWINGS

Aspects of the present disclosure may be more completely understood in consideration of the following detailed description of various embodiments in connection with the accompanying drawings, in which:

FIG. 1 is a schematic diagram illustrating an example self-powered electrical system;

FIG. 2 is a perspective view of a self-powered lighting system affixed to a heating source;

FIG. 3 is an perspective view of the self-powered lighting system of FIG. 2;

FIG. 4 is an alternate perspective view of the self-powered lighting system of Figure 2;

FIG. 5 is a front view of the self-powered lighting system of FIG. 2;

FIG. 6 is a side view of the self-powered lighting system of FIG. 2; and

FIG. 7 is a rear view of the self-powered lighting system of FIG. 2.

FIG. 8 is an alternative front view of the self-powered lighting system incorporated into a shower.

FIG. 9 is a perspective view of a portion of the shower of FIG. 8.

### DETAILED DESCRIPTION

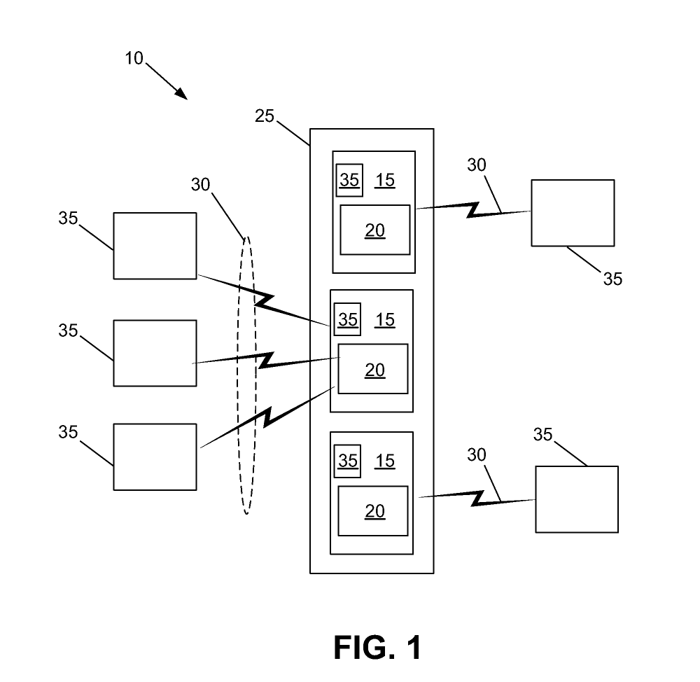

Referring now to FIG. 1, a schematic diagram 10 illustrating a self-powered electrical system is shown in accordance with principles of the present disclosure. In general, the self-powered electrical system is configured such that heat energy associated with a heating source is converted to electric energy. Subsequently, the electrical energy can be utilized to power one or more electrical accessories or devices. More specifically, the self-powered electrical system includes at least one or more housing modules 15 where each respective housing module 15 houses a thermoelectric device 20. In an example embodiment, the one or housing modules 15 can be affixed to a heating source 25 such that heat energy associated with the heating source can be utilized to establish a temperature gradient across the thermoelectric device. In this manner, by virtue of a thermoelectric effect, heat energy is converted into electricity that can be transferred via a power transfer medium 30 (i.e., power cable, air) to one or more electrical devices 35, as described in further detail below.

Several example devices include a personal digital assistant (PDA), a laptop computer, a flashlight, a motor, a light emitting diode, a radio, or a cooler. In one aspect, one or more electrical devices 35 can be located external to a respective housing module 15, as depicted. In a second aspect, one or more electrical devices 35 can be integrally formed with a respective housing module 15.

In general, in one example embodiment, the self-powered electrical system can be a self-powered lighting system that may be mounted to a portion of the heating source 25, described in further detail below. It will be appreciated that there are many ways that the self-powered lighting system can be mounted. For example, the self-powered lighting system may be magnetically mounted provided that both the self-powered lighting system and the heating source is formed or partially formed from a material having magnetic properties. Alternatively, a mechanical mounting scheme can be used such as a hooking mechanism, a clipping mechanism, or a fastening mechanism. Further still, a strapping system may be employed to strap the self-powered lighting system to the heating source.

In the described embodiment the self-powered lighting system can include a thermoelectric device whereby heat energy associated with the heating source can be converted into electrical energy to power a light source. In general, the self-powered lighting system can be mounted to the heating source such that a heat sink surface associated with the thermoelectric device is in direct contact with a portion of the heating source, and a cold sink surface associated with the thermoelectric device is located opposite of the first surface. In this respect, the term “heat sink” and “cold sink” are used to indicate the relative temperature of the two sinks, which are structures for absorbing and dissipating heat. The cold sink is that which is at a lower temperature than the heat sink during operation of the thermoelectric device.

In accordance with the described embodiment, the thermoelectric device employed can utilize the Seebeck effect, which is the conversion of a temperature gradient into electricity. A thermoelectric device utilizing the Seebeck effect relies on a voltage being created in the presence of a temperature difference between two dissimilar metals or semiconductor materials contacting each other, which in turn causes a direct current to flow into the conductors when they form a complete loop.

In one example embodiment, the heating source 25 can be configured as a heating device such as barbecue oven, or grill, to cook or heat a food product. The barbecue oven can include at least a first section and a second section connectively coupled together via one or more hinges. There are many ways to configure the first section and second section to cook or heat a food product. In one embodiment the first section of the two-piece enclosure is configured as a stationary housing having a bottom wall, a plurality of first side walls and a plurality first end walls which together define an open space within the first section. Additionally, the interior of the first section can include a plurality of integral mounting features such that a grill grating can be mounted and supported.

The second section of the two-piece enclosure is configured as a cover that is hingedly connected to the first section such that the second section is movable with respect to the stationary first section. The second section can have one or more features to facilitate handling and additionally can include a top wall, a plurality of second side walls and a plurality of second end walls, thereby defining on open space within the second section. Subsequently, upon closing the second section to the first section a sealed heating space is formed therein. Additional features integral with the second section may be provided such as an adjustable vent to control temperature and/or a temperature gauge to monitor temperature.

In general, a heating source can be formed from an alloyed, heat-resistant material such as stainless steel, which may or may not be magnetic based on the percentage of the respective alloyed material. Additionally, there are many ways with which to heat a heating source. For example, the exterior of a bottom wall can be exposed to an open flame or alternatively, an internal volume of the heating source can be directly heated via the burning of natural gas.

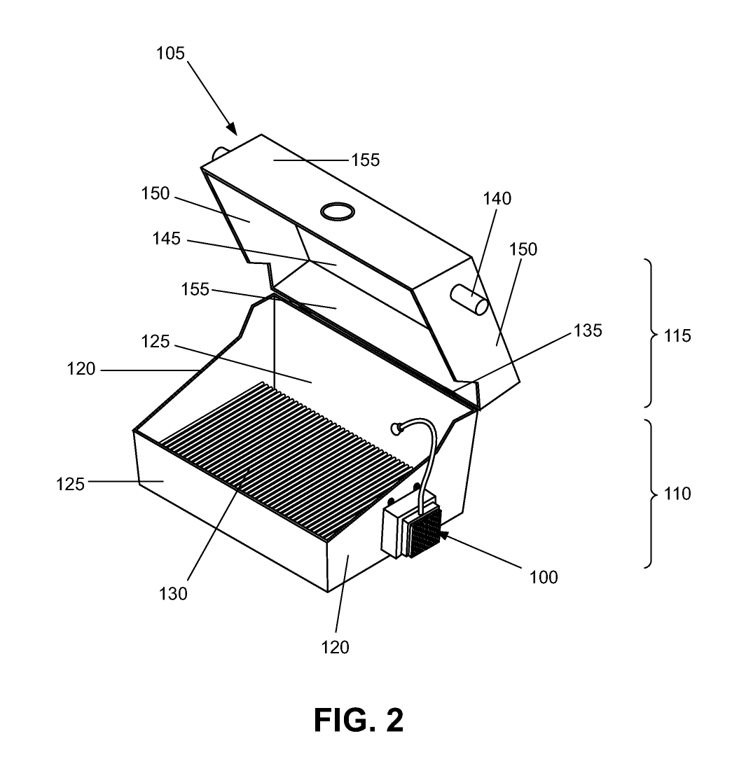

Referring now to FIG. 2, there is illustrated a self-powered lighting system 100 generally mounted to a heating device 105 such as a barbecue oven or grill. The self-powered lighting system 100 is one example embodiment of the portable self-powered electrical system 10, as depicted and described with reference to FIG. 1. In the example embodiment, the heating device 105 is a two-piece enclosure comprising a first section 110 and a second section 115 connectively coupled together via one or more hinges 135. The first section 110 of the heating device 105 is configured as a stationary housing having a bottom wall (not shown), a plurality of side walls 120 and a plurality of end walls 125 which together define an open space within the first section 110. Additionally, the interior of the first section 110 can include a plurality of integral mounting features (not shown) such that a grill grating 130 can be mounted and supported.

The second section 115 is configured as a cover having one or more features such as one or more handles 140 to facilitate handling and opening of the heating device 105. In the example embodiment the second section 115 can include a top wall 145, a plurality of first side walls 150 and first end walls 155 with thereby defining on open space within the second section 115. Subsequently, upon closing the movable second section 115 to the stationary first section 110 a sealed heating space is formed therein.

It will be appreciated that the heating device 105 may be formed of any conventional materials, such as a stainless steel alloy having magnetic properties, and can be formed in any configuration.

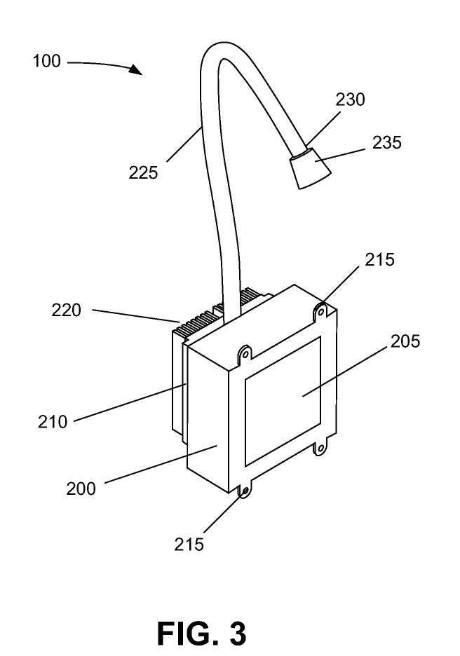

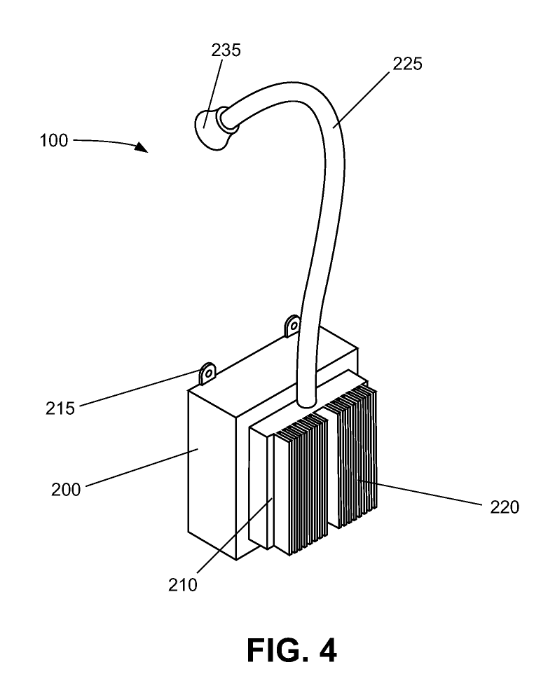

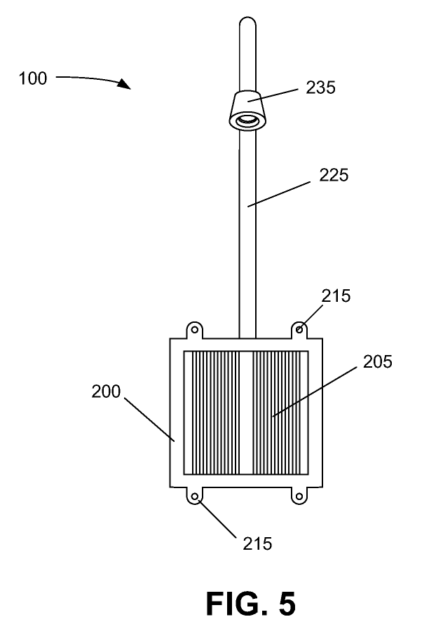

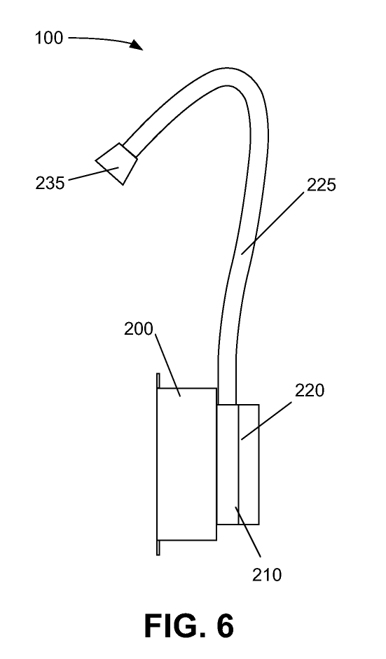

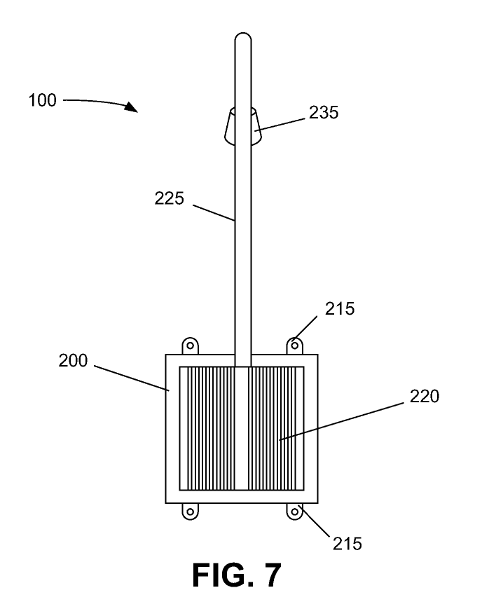

Referring now to FIGS. 3-7, several different views of the self-powered lighting system 100 are shown. In the example embodiment, the self-powered lighting system 100 includes a housing 200. It will be appreciated that the housing 200 may be formed of many different materials. For example, the housing 200 may be formed from a heat-resistant durable material, such as a such as a stainless steel alloy, having magnetic properties such that the self-powered lighting system 100 can be easily coupled to a heating device 105, provided the heating device 105 is formed or partially formed from a magnetic material. Alternatively, the housing 200 may be formed of a non-magnetic heat-resistant material wherein one or magnets placed inside the housing 200 to facilitate magnetic coupling to a magnetic heating device 105.

There are many methods with which to mount the self-powered lighting system 100 to the heating device 105. For example, in the depicted embodiment a plurality of fastening features 215 are integrally formed with the housing 200. The plurality of fastening features 215 may be employed to mount the self-powered lighting system 100 to the heating device 105 via a nut and bolt assembly. Alternatively, a hook and strap method may be used in conjunction with the plurality of fastening features 215 to securely mount the self-powered lighting system 100 to the heating device 105. It will be appreciated that the housing 200 can be formed such that many different types of integral features can be included to facilitate mounting the self-powered lighting system 100 to the heating device 105.

In the example embodiment, integral with the housing 200, is a thermoelectric device which includes a generator (not shown), a hot sink 205 located at a front side of the housing 200 and a cold sink 210 located at a back side of the housing. Associated with the cold sink 210 is a plurality of fins 220 to assist with the dissipation of heat.

A flexible arm 225 is additionally integral with the housing 200. At a terminal end 230 of the flexible arm 225 is a light fixture 235, such as an LED, which is powered by the thermoelectric device. The flexible arm 225 is movable and can be shaped to allow for desired positioning of the light fixture 235. In an alternative example embodiment it will be appreciated that one or more light fixtures 235 may be provided.

In operation of the self-powered lighting system 100 mounted to the heating device 105, an application of heat to the heating device will cause the heat to warm portions of the first section 110 and the second section 115. This in turn will heat the hot sink 205, thereby setting up a temperature gradient between the hot sink 205 and the cold sink 220. By virtue of the Seebeck effect a flow of direct current electricity will result. The electricity thus generated can be used to operate the light fixture 235 wherein the generated light will then be permitted to shine down on the heating device 105. When the heat source is removed from the heating device 105 the temperature gradient between the hot sink 205 and the cold sink 220 will be is reduced. Consequently, the power delivered to the light fixture 235 will cease and the light will fade away.

In the example embodiment, supporting electronics may additionally be located within housing 200 to sufficiently enable the distribution of power to the light fixture 235. For example, a printed circuit board (not shown) having a plurality of discrete electrical components such as transistors, capacitors, inductors, resistors and functional electronics such as a voltage regulator and the like may be included.

It is noted that in the above example embodiment a thermoelectric device used in conjunction with a barbecue grill provides power to a lighting system. However, it will be appreciated that a barbeque grill is just one example of a heat source. Consistent with the principals described herein, any heat source such as a gas or wood-powered fire, electric stove, battery powered device, or hot water may be utilized.

For example, the self-powered lighting system can be used such that hot water from a shower or water faucet causes the light to light up. Thus, when the water is hot in a shower, the light would come on. Conversely, when the shower is complete, the light would automatically turn off.

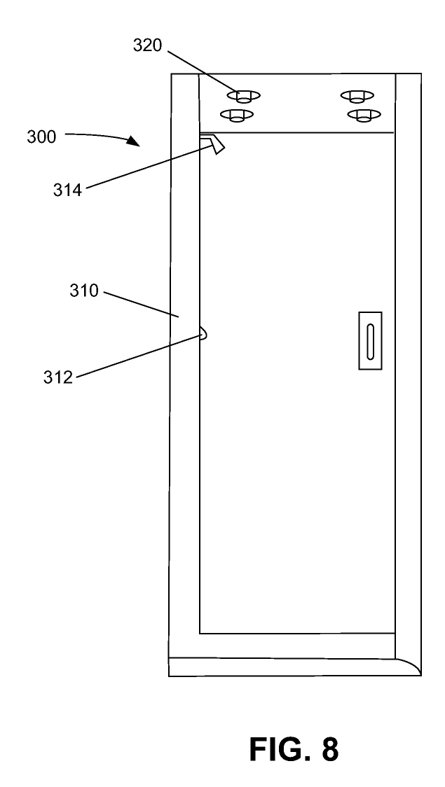

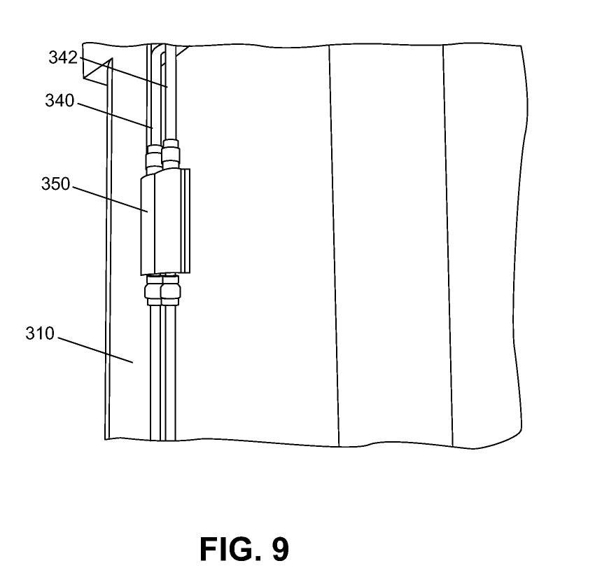

Referring now to FIGS. 8 and 9, the self-powered lighting system is shown incorporated into an example shower 300. The self-powered lighting system is designed to use the temperature gradient between the hot and cold water pipes 340, 342 that supply water to a shower 300.

Upon opening of the taps 312, the hot water and the cold water pass through their respective pipes 340, 342 and exit a shower head 314. A temperature difference is created. A thermoelectric module 350 is sandwiched between a hot water sink and a cold water sink.

The temperature difference across the module 350 generates (Seebeck effect) a dc current. This current can power LED lights 320 inside the shower enclosure 310. The current can also be used to trigger other events, such as a relay to start the bathroom ventilator, or any other electric device.

So once the temperature differential is created between the pipes 340, 342 in use, the lights 320 in the shower will turn on. When the water is turned off, the temperature differential will fade and the lights 320 will fade off, and the ventilator relay will switch off as well.

The preceding embodiments are intended to illustrate without limitation the utility and scope of the present disclosure. Those skilled in the art will readily recognize various modifications and changes that may be made to the embodiments described above without departing from the true spirit and scope of the disclosure.

What is claimed is:

1. A portable self-powered electrical system comprising:
a housing module;
a thermoelectric device positioned in the housing module; and
a power transfer medium, the thermoelectric device providing power to at least one electronic device via the power transfer medium;
wherein the thermoelectric device converts heat energy from a heat source into electrical energy.

2. The electrical system of claim 1, wherein the thermoelectric device includes a heat sink exposed from a first side of the housing module and a cold sink positioned on a second side of the housing module.

3. The electrical system of claim 2, wherein said cold sink includes a plurality of heat radiating surfaces.

4. The electrical system of claim 1, wherein the thermoelectric device utilizes the Seebeck effect to convert heat energy from the heat source into electrical energy.

5. The electrical system of claim 1, wherein the power transfer medium is a power cable.

6. The electrical system of claim 1, wherein the power transfer medium is air.

7. The electrical system of claim 1, wherein the housing module is affixed to a barbecue grill.

8. The electrical system of claim 7, wherein the housing module is magnetic such that the housing module can be magnetically affixed to a barbecue grill formed or partially formed from a material having magnetic properties.

9. The electrical system of claim 1, wherein the housing module is affixed to a shower or water faucet.

10. The electrical system of claim 1, wherein the at least one electronic device includes one of:
a. a personal digital assistant;
b. a laptop computer;
c. a flashlight;
d. a light emitting diode;
e. a radio;
f. a motor; or
g. a cooler;

11. A portable self-powered lighting system comprising:
a housing;
a thermoelectric device positioned in the housing; and
an arm connected to the housing, the thermoelectric device providing power via the arm to the one or more light fixtures;
wherein the thermoelectric device converts heat energy from a heat source into electrical energy to power at least one light.

12. The lighting system of claim 11, wherein the thermoelectric device includes a heat sink exposed from a first side of the housing and a cold sink positioned on a second side of the housing.

13. The lighting system of claim 12, wherein said cold sink includes a plurality of heat radiating surfaces.

14. The lighting system of claim 11, wherein the one or more light fixtures include one or more light emitting diode lights electrically connected to the thermoelectric device.

15. The lighting system of claim 11, wherein the arm is flexible and can be shaped to provide a desired positioning of the one or more light fixtures.

16. The lighting system of claim 11, wherein the housing is affixed to a barbecue grill.

17. The lighting system of claim 16, wherein the housing is magnetic such that the housing can be magnetically affixed to a barbecue grill formed or partially formed from a material having magnetic properties

18. The lighting system of claim 11, wherein the housing is affixed to the barbecue grill via a hook and strap.

19. The lighting system of claim 11, wherein the housing is affixed to a shower or water faucet.

20. The lighting system of claim 11, wherein the thermoelectric device utilizes the Seebeck effect to convert heat energy from a heat source into electrical energy.
